(19) United States
(12) Patent Application Publication
(10) Pub. No.: US 2025/0006631 A1
(43) Pub. Date: Jan. 2, 2025

(54) INTEGRATED INDUCTOR INCLUDING MAGNETIC LAYER

(71) Applicant: QUALCOMM Incorporated, San Diego, CA (US)

(72) Inventors: Jui-Yi CHIU, Taichung City (TW); Kai LIU, Phoenix, AZ (US); Jonghae KIM, San Diego, CA (US)

(21) Appl. No.: 18/343,595

(22) Filed: Jun. 28, 2023

(51) Int. Cl. H01L 23/522; H01F 17/00; H01F 41/04; H01L 21/56; H01L 23/00

(52) U.S. Cl. CPC H01L 23/5227; H01F 17/0013; H01F 41/041; H01L 21/565; H01L 24/16; H01L 28/10; H01F 2017/0066; H01L 2224/16225; H01L 2924/186; H01L 2924/19042

(57) ABSTRACT

An inductive device includes a first set of conductive lines, a second set of conductive lines, and conductive pillars connecting the first set of conductive lines to the second set of conductive lines to form an integrated inductor. The inductive device also includes one or more magnetic layers extending along a length of the integrated inductor and within an aperture of the integrated inductor.

### FIELD

Various features relate to inductive devices.

### BACKGROUND

Integrated circuit (IC) technology has achieved great strides in advancing computing power through miniaturization of active components. Integrated passive components have also been miniaturized, and the trend for further miniaturization of such components continues. Passive inductive elements are often some of the larger elements in a circuit in part because characteristic electrical properties of an inductive element are related to physical dimensions of the inductive element. For example, inductance of the inductive element is related to an aperture of a coil of the inductive element, and current carrying capacity of the inductive element is related to dimensions of conductive elements of the coil. Due to these and other factors, there is a need for high current, high inductance inductive devices that have a small form factor.

### SUMMARY

Various features relate to integrated circuit devices.

One example provides an inductive device that includes a first set of conductive lines and a second set of conductive lines. The inductive device includes conductive pillars connecting the first set of conductive lines to the second set of conductive lines to form an integrated inductor. The inductive device also includes one or more magnetic layers extending along a length of the integrated inductor and within an aperture of the integrated inductor.

Another example provides a device that includes an integrated device. The integrated device includes a first set of conductive lines and a second set of conductive lines. The integrated device includes conductive pillars connecting the first set of conductive lines to the second set of conductive lines to form an integrated inductor. The integrated device also includes one or more magnetic layers extending along a length of the integrated inductor and within an aperture of the integrated inductor.

Another example provides a method for fabricating an inductive device. The method includes forming a first set of conductive lines. The method includes forming one or more magnetic layers above the first set of conductive lines. The method includes forming conductive pillars connected to the first set of conductive lines. The method also includes forming a second set of conductive lines above the one or more magnetic layers and connected to the conductive pillars to form an integrated inductor. The one or more magnetic layers extend along a length of the integrated inductor and within an aperture of the integrated inductor.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a schematic cross sectional profile view of a device that includes an exemplary integrated inductor including multiple magnetic layers.

FIG. 2 illustrates a schematic cross sectional profile view of a device that includes an exemplary integrated inductor including a magnetic layer.

FIG. 3 illustrates a schematic cross sectional profile view of a device that includes an exemplary integrated inductor including a magnetic layer.

FIG. 4 illustrates a schematic cross sectional profile view of a device that includes an exemplary integrated inductor including multiple magnetic layers.

FIG. 5 illustrates a schematic cross sectional profile view of a device that includes an exemplary integrated inductor including multiple magnetic layers.

FIG. 6A illustrates a schematic top view of a device that includes an exemplary integrated inductor including multiple magnetic layers.

FIG. 6B illustrates a schematic perspective view of the device of FIG. 6A.

FIG. 6C illustrates a schematic cross sectional profile view of a portion of the device of FIG. 6A.

FIGS. 7A, 7B, and 7C illustrate an exemplary sequence for fabricating an exemplary integrated inductor that includes multiple magnetic layers.

FIG. 8 illustrates an exemplary flow diagram of a method for fabricating an exemplary integrated inductor that includes a magnetic layer.

FIG. 9 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

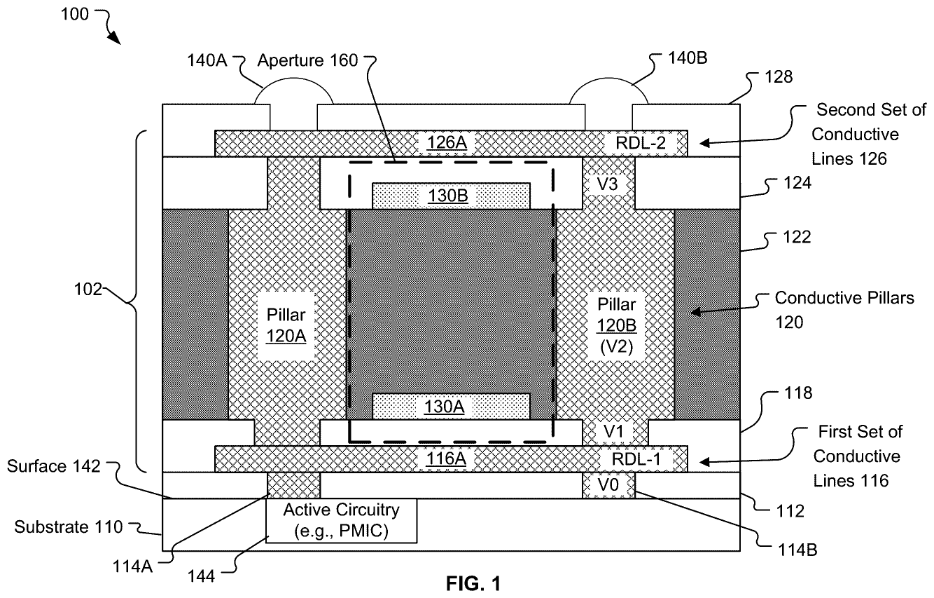

In some drawings, multiple instances of a particular type of feature are used. Although these features are physically and/or logically distinct, the same reference number is used for each, and the different instances are distinguished by addition of a letter to the reference number. When the features as a group or a type are referred to herein e.g., when no particular one of the features is being referenced, the reference number is used without a distinguishing letter. However, when one particular feature of multiple features of the same type is referred to herein, the reference number is used with the distinguishing letter. For example, referring to FIG. 1, multiple magnetic layers 130 are illustrated and associated with reference numbers 130A and 130B. When referring to a particular one of these magnetic layers, such as a magnetic layer 130A, the distinguishing letter “A” is used. However, when referring to any arbitrary one of these magnetic layers or to these magnetic layers as a group, the reference number 130 is used without a distinguishing letter.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Aspects of the present disclosure are directed to an integrated inductor device that may be formed on a wafer surface using wafer-level processing. In some aspects, the integrated inductor device has a three-dimensional (3D) solenoid inductance design and includes one or more flat magnetic layers. The one or more magnetic layers are within an aperture of the inductor and extend along the length of the inductor.

### Exemplary Device Including an Integrated Inductor Comprising Magnetic Layer(s)

FIG. 1 illustrates a schematic cross sectional profile view of a device 100 that includes an exemplary integrated inductor 102 on a substrate 110. The integrated inductor 102 is configured as a solenoid having coils formed by a first set of conductive lines 116, a second set of conductive lines 126, and conductive pillars 120 connecting the first set of conductive lines 116 to the second set of conductive lines 126. The integrated inductor 102 also includes one or more magnetic layers 130 within an aperture 160 of the integrated inductor 102.

The substrate 110 (e.g., a wafer, die, chip, etc.) includes integrated active circuitry 144, such as a plurality of transistors and/or other circuit elements arranged and interconnected to form logic cells, memory cells, etc. The integrated active circuitry 144 may be coupled to one or more electrical contacts at a substrate surface 142 to enable electrical communication with one or more components that are external to the substrate 110. In a particular example, the integrated active circuitry 144 corresponds to a power management integrated circuit (PMIC) and the substrate 110 corresponds to a PMIC die or chip. Components of the integrated active circuitry 144 can be formed in and/or over a semiconductor substrate. Different implementations can use different types of transistors, such as a field effect transistor (FET), planar FET, finFET, a gate all around FET, or mixtures of transistor types. In some implementations, a front end of line (FEOL) process may be used to fabricate the integrated active circuitry 144 in and/or over the semiconductor substrate.

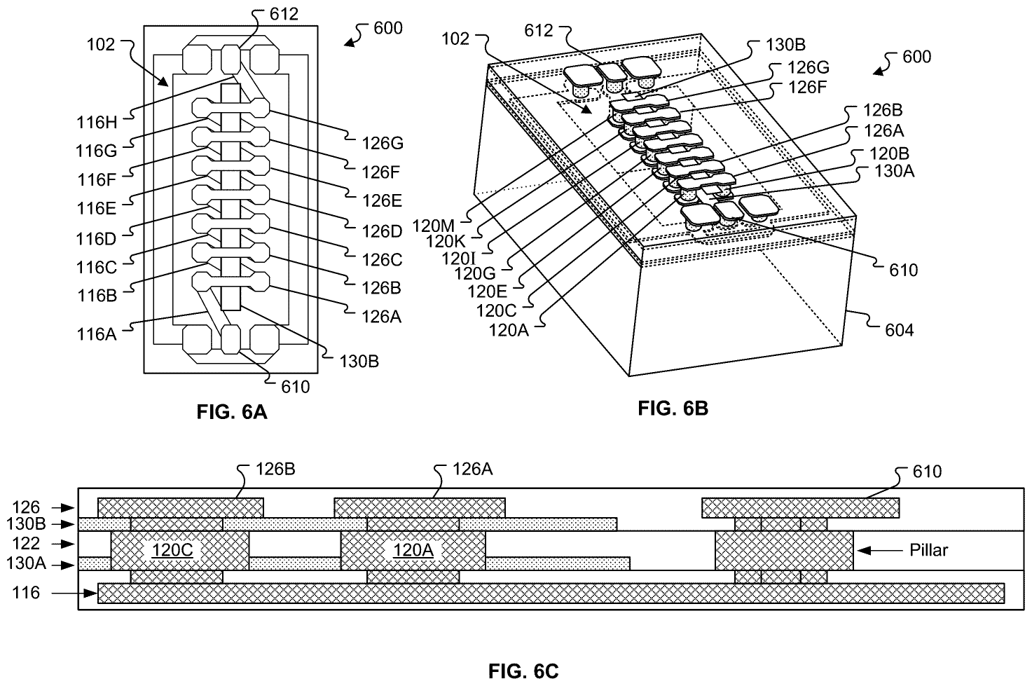

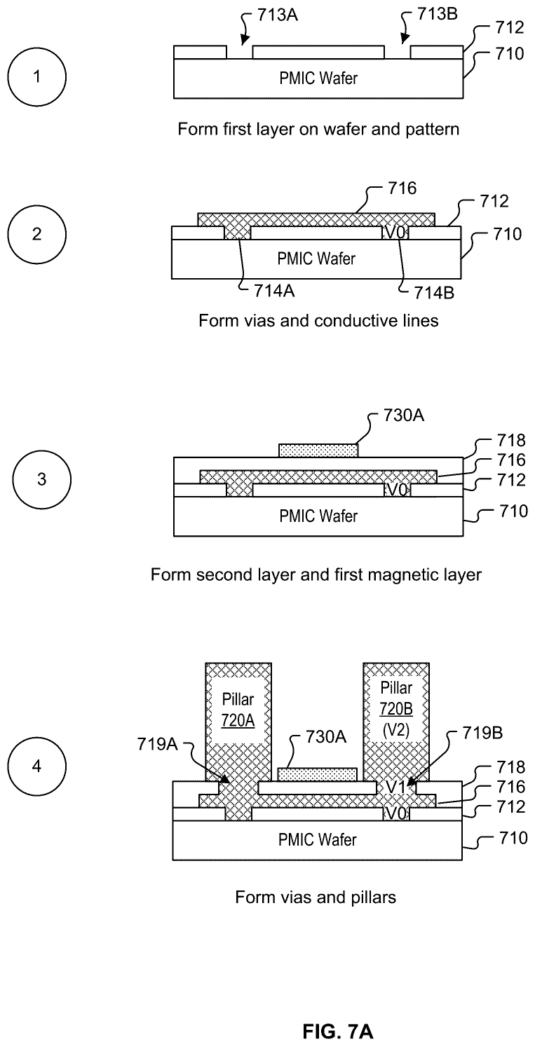

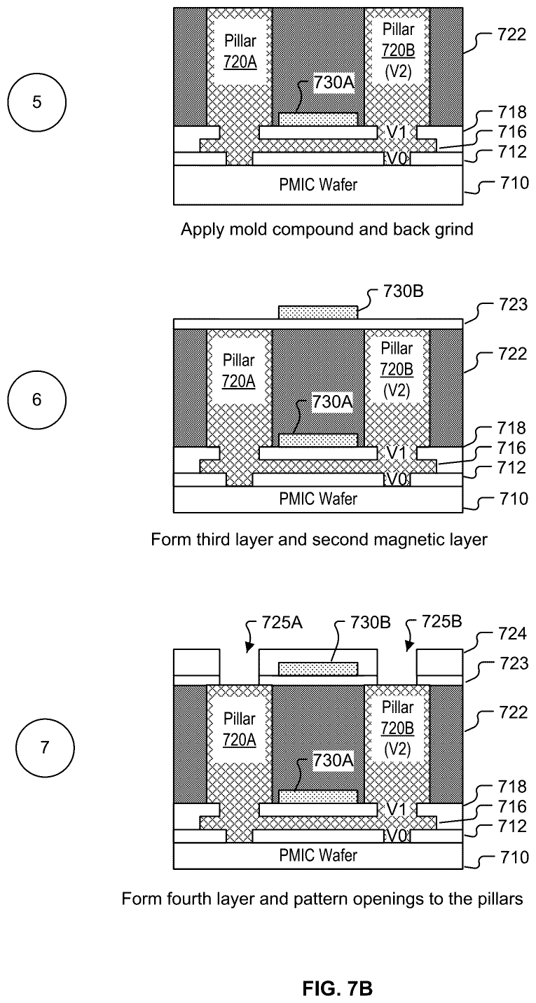

The first set of conductive lines 116 is above the surface 142 and includes a representative conductive line 116A that electrically connects to one or more of the conductive pillars 120 according to a solenoid winding configuration, such as described further with reference to FIG. 6A and FIG. 6B. One or more conductive lines 116 of the first set of conductive lines 116 are coupled to one or more vias, such as a via 114A and a via 114B, that extend through an insulation layer 112 to the substrate 110. For example, the via 114A may electrically connect the conductive line 116A to the active circuitry 144 and may function as an input to the integrated inductor 102. According to an aspect, the vias 114 are in a first via layer (“V0”), and the first set of conductive lines 116 are in a first redistribution layer (“RDL-1”).

The conductive pillars 120 include a conductive pillar 120A and a conductive pillar 120B. In some implementations, the conductive pillars 120 are formed of photoresist-defined electroplated copper and have a relatively large height and diameter (e.g., “megapillars”). In a particular example, each of the conductive pillars 120 has a height in the range of 75-110 micrometers and a diameter in the range of 75-110 micrometers, although in other examples the conductive pillars 120 can have larger or smaller heights and/or larger or smaller diameters. According to an aspect, the conductive pillars 120 are in a third via layer (“V2”) and electrically connected to vias of a second via layer (“V1”) that extend through an insulation layer 118 to the conductive lines 116.

A mold compound 122 at least partially encapsulates the conductive pillars 120 between the first set of conductive lines 116 and the second set of conductive lines 126. According to some aspects, the mold compound 122 includes an epoxy material.

The second set of conductive lines 126 includes a representative conductive line 126A that electrically connects the conductive pillar 120A to the conductive pillar 120B or to another conductive pillar 120 (not shown) according to the solenoid winding configuration, such as described further with reference to FIG. 6A and FIG. 6B. According to an aspect, the conductive lines 126 are in a second redistribution layer (“RDL-2”) and electrically connected to vias of a fourth via layer (“V3”) that extend through an insulation layer 124 to the conductive pillars 120. According to an aspect, one or more of the conductive lines 126 are further coupled to one or more solder balls 140 (e.g., a solder ball 140A and/or a solder ball 140B) or other electrical contacts that extend through an upper insulation layer 128.

In a particular implementation, the insulation layers 112, 118, 124, and 128 each include a polyimide material or other polymer material. Although described as “insulation” layers, it should be understood that the layers 112, 118, 124, and 128 may serve various functions; for example, the layers 112, 118, 124, and 128 may function as electrical isolation layers, passivation layers, protective layers during sputtering or other fabrication processes, etc.

The aperture 160 is bordered by the conductive pillar 120A, the conductive pillar 120B, the conductive line 116A, and the conductive line 126A and indicates a cross-sectional area of the interior of the integrated inductor 102 that is perpendicular (e.g., normal) to the magnetic field lines through the interior of the integrated inductor 102. Because the inductance of the integrated inductor 102 is generally proportional to the size of the aperture 160 (among other factors), the inductance can be increased by increasing the size of the aperture 160. The inductance is further increased by the presence of the one or more magnetic layers 130 that are in the aperture 160 and that extend along a length of the integrated inductor 102 (e.g., in a direction into/out of the page in the orientation illustrated in FIG. 1), as described further below.

As illustrated, the one or more magnetic layers 130 in the integrated inductor 102 of FIG. 1 includes two magnetic layers 130A, 130B. The magnetic layer 130A is positioned above the first set of conductive lines 116 in a lower portion of the aperture 160. The magnetic layer 130A is below the mold compound 122, and the insulation layer 118 is between the magnetic layer 130A and the first set of conductive lines 116. The magnetic layer 130B is positioned below the second set of conductive lines 126 in an upper portion of the aperture 160. The magnetic layer 130B is above the mold compound 122, and the insulation layer 124 is between the magnetic layer 130B and the second set of conductive lines 126.

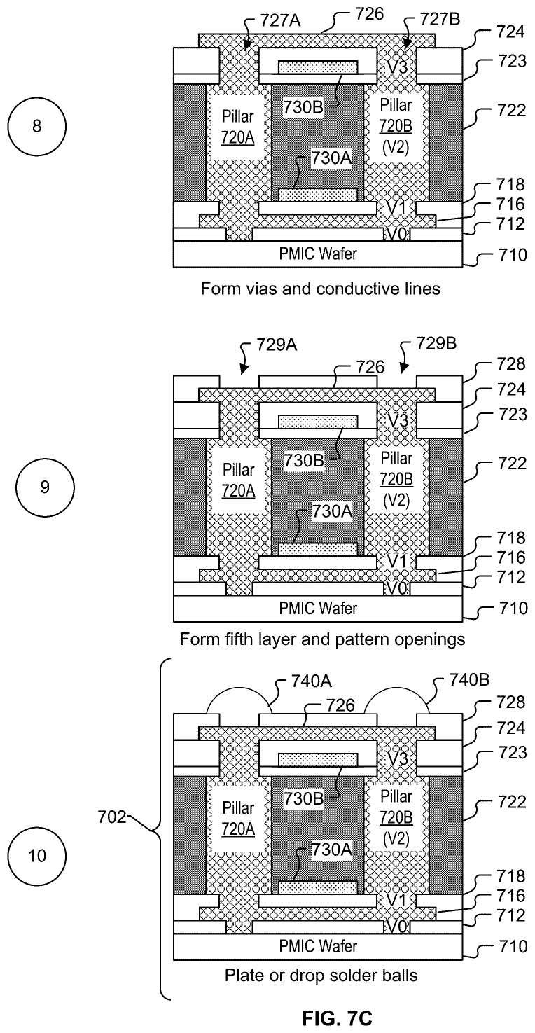

According to some implementations, the one or more magnetic layers 130 include one or more of CoZrTa, CoZrTaB, or FeCoB and may be formed via a sputter deposition process. As described further with reference to FIG. 7A and FIG. 7B, the one or more magnetic layers 130 can be formed using wafer-level processing techniques such as patterning, etching, and deposition techniques that can be performed relatively quickly, with low cost and high reliability, as compared to conventional approaches for providing high-inductance structures using wafer-level processes.

According to some implementations, at least one of an input of the integrated inductor 102 and an output of the integrated inductor 102 is coupled to a solder ball 140. For example, in some configurations, an input of the integrated inductor 102 is coupled to the active circuitry 144 of the substrate 110 (e.g., a PMIC), and an output of the integrated inductor 102 is coupled to a solder ball 140. To illustrate, the input of the integrated inductor 102 may be at the via 114A that connects the conductive line 116A to the active circuitry 144 at a first end of the integrated inductor 102. A 3D solenoid that is formed via connections between the conductive pillars 120, the conductive lines 116, and the conductive lines 126 provides a rectangular helical current path through the integrated inductor 102, and the current path may terminate at the solder ball 140A or at the solder ball 140B at the output of the integrated inductor 102. In other configurations, both of the input and the output of the integrated inductor 102 are coupled to respective solder balls 140. To illustrate, the solder ball 140A may connect to the conductive line 126A at an input to the integrated inductor 102, and the current path through the integrated inductor 102 may terminate at the solder ball 140B at an output of the integrated inductor 102.

One strategy that is used to provide high inductance at a wafer surface includes forming an inductor with a single linear conductive trace that sits above a flat magnetic layer and below a dome or shell of magnetic material. With such an approach, an inductor with dimensions of about 1 millimeter (mm) long and 0.33 mm wide can have an inductance of around 6-10 nanohenry (nH), which can satisfy the area and inductance criteria (e.g., 6 nH) for a 100 megahertz (MHz) switching frequency PMIC application. However, fabrication of the magnetic dome is a relatively long and expensive process that can involve multiple mask layers and physical vapor deposition of thick dome material. In comparison, in a particular example, the integrated inductor 102 may provide approximately 11 nH in the same footprint (1 mm×0.33 mm) using a solenoid configuration that encircles the flat magnetic layers 130A, 130B and that can be fabricated using wafer-level processing techniques (e.g., sputtering photoresist-defined flat layers) that can be performed relatively quickly, with lower cost, and with higher reliability in the presence of mechanical stress, as compared to fabrication of a magnetic dome. Thus, a technical benefit of the integrated inductor 102 using a solenoid configuration that encircles the flat magnetic layers 130 is shorter fabrication time, lower complexity with fewer mask layers, and higher reliability to obtain comparable or improved performance (e.g., high inductance) within the same footprint.

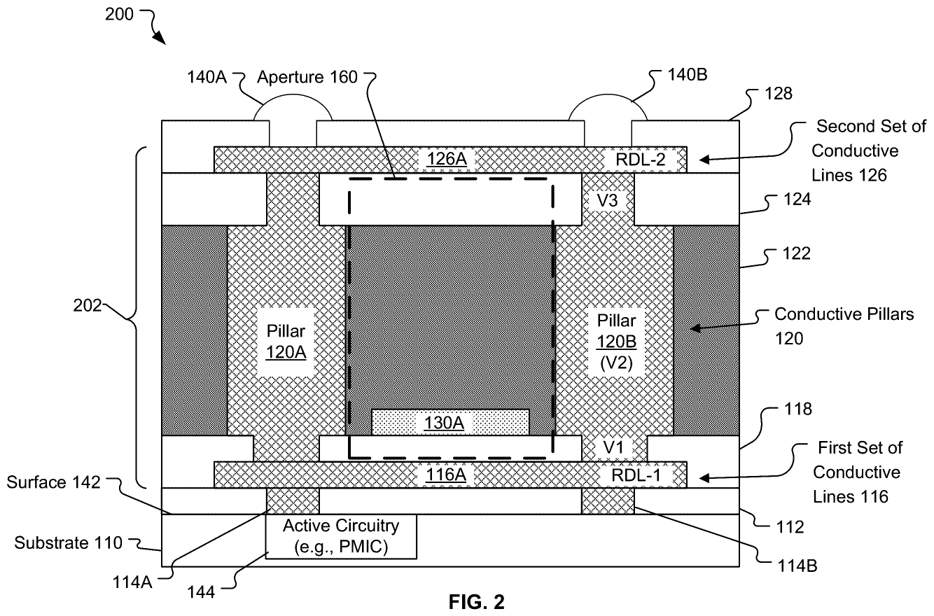

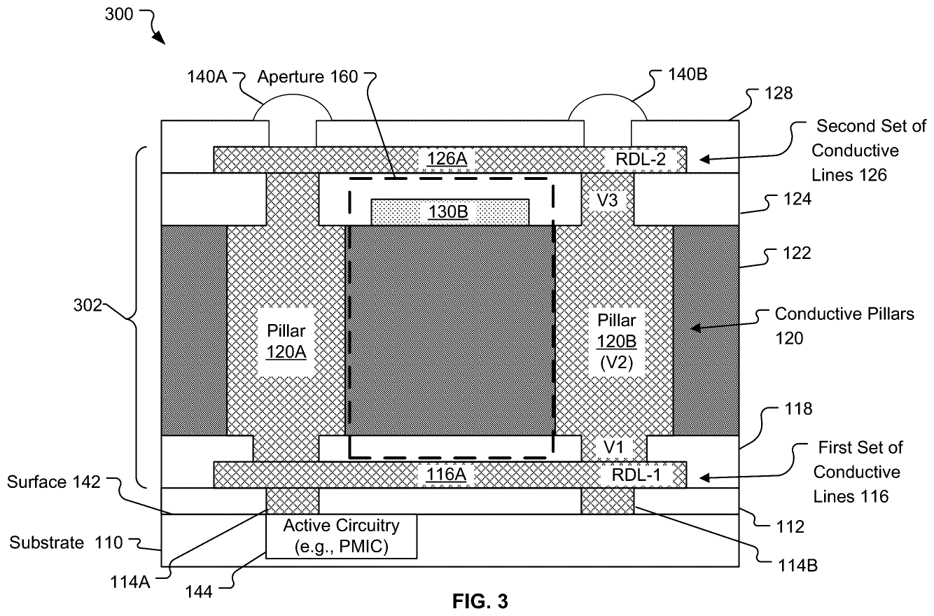

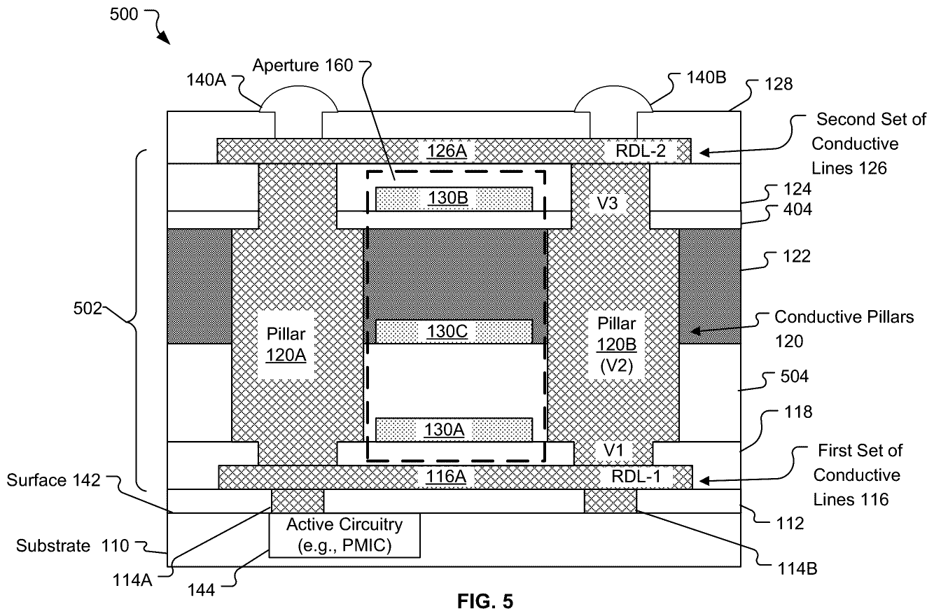

Although the integrated inductor 102 depicted in FIG. 1 has two magnetic layers 130 within the aperture 160, in other implementations the integrated inductor 102 includes a single magnetic layer 130, such as described further with reference to FIG. 2 and FIG. 3, or includes more than two magnetic layers 130, such as described further with reference to FIG. 5.

Although FIG. 1 illustrates the integrated inductor 102 on the surface 142 of the substrate 110 (e.g., a PMIC), in other implementations the integrated inductor 102 is within or on a package substrate, such as described in further detail with reference to FIG. 6B.

FIGS. 2-5 each illustrate a schematic cross sectional profile view of a respective device that includes an exemplary integrated inductor. The devices of FIG. 2-5 each include many of the same components and features as are described above with reference to FIG. 1. Such components and features are physically and operationally the same as described above with reference to FIG. 1 and are labeled in FIGS. 2-5 using the same reference numbers.

FIG. 2 depicts a device 200 that includes an exemplary integrated inductor 202 that corresponds to the integrated inductor 102 of FIG. 1. The integrated inductor 202 includes the lower magnetic layer 130A and omits the upper magnetic layer 130B of FIG. 1. As compared to the particular example of the integrated inductor 102 described above with reference to FIG. 1 in which the integrated inductor 102 has a 1 mm×0.33 mm footprint and an inductance of approximately 11 nH inductance with two magnetic layers 130A and 130B, a particular example of the integrated inductor 202 having the 1 mm×0.33 mm footprint with the single magnetic layer 130A in the aperture 160 has an inductance of approximately 7.4 nH. Thus, a technical benefit of including the lower magnetic layer 130A and omitting the upper magnetic layer 130B of FIG. 1 is that the resulting integrated inductor 202 can be fabricated using fewer processing steps and using less magnetic material than is used for fabrication of the integrated inductor 102 while still providing sufficient inductance (e.g., 7.4 nH) to satisfy an inductance criteria (e.g., 6 nH for a 100 MHz switching frequency PMIC application).

FIG. 3 depicts a device 300 that includes an exemplary integrated inductor 302 that corresponds to the integrated inductor 102 of FIG. 1. The integrated inductor 302 includes the upper magnetic layer 130B and omits the lower magnetic layer 130A of FIG. 1. As compared to the particular example of the integrated inductor 102 of FIG. 1 having a 1 mm×0.33 mm footprint and an inductance of approximately 11 nH with two magnetic layers 130A and 130B, a particular example of the integrated inductor 302 having the 1 mm×0.33 mm footprint with the single magnetic layer 130B in the aperture 160 has an inductance of approximately 7.2 nH. Thus, a technical benefit of including the upper magnetic layer 130B and omitting the lower magnetic layer 130A of FIG. 1 is that the resulting integrated inductor 302 can be fabricated using fewer processing steps and using less magnetic material than is used for fabrication of the integrated inductor 102 while still providing sufficient inductance (e.g., 7.2 nH) to satisfy an inductance criteria (e.g., 6 nH for a 100 MHz switching frequency PMIC application).

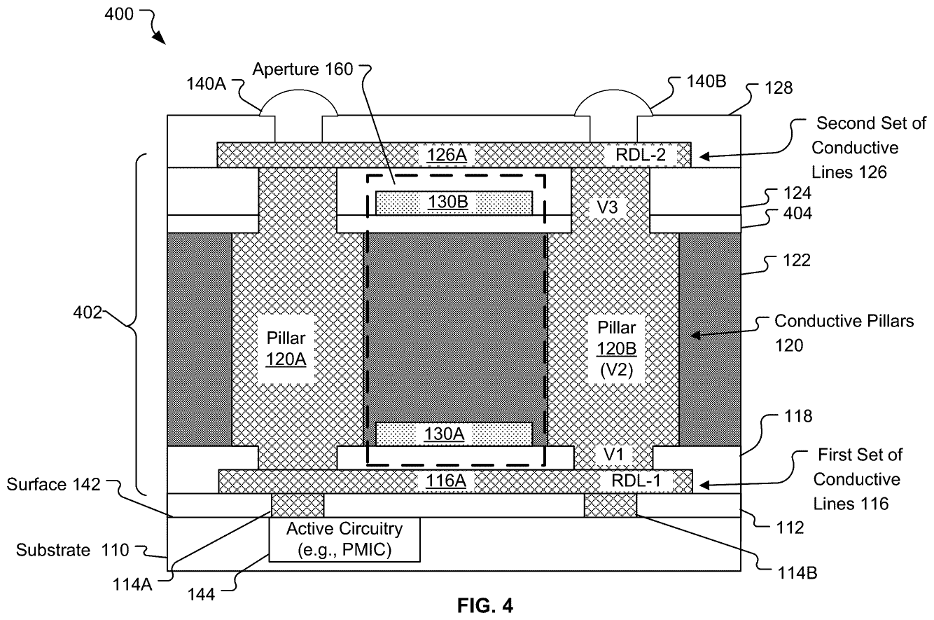

FIG. 4 depicts a device 400 that includes an exemplary integrated inductor 402 that corresponds to the integrated inductor 102 of FIG. 1. As compared to the integrated inductor 102 of FIG. 1, an insulation layer 404 is between the mold compound 122 and the insulation layer 124, and the magnetic layer 130B is on the insulation layer 404.

Because sputtering deposition of the magnetic layer 130B is an energetic process that could potentially cause epoxy material to eject from the upper surface of the mold compound 122, the insulation layer 404 can be used to protect the mold compound 122 during fabrication. For example, the insulation layer 404 can include a polyimide material that is more robust to sputtering deposition than the mold compound 122, which may reduce or eliminate ejection of surface material during sputtering deposition. Thus, a technical benefit of incorporating the insulation layer 404 is the reduction or elimination of ejected material that may contaminate the sputtering chamber during deposition of the magnetic layer 130B.

FIG. 5 depicts a device 500 that includes an exemplary integrated inductor 502 that corresponds to the integrated inductor 102 of FIG. 1 and in which the one or more magnetic layers 130 includes three magnetic layers—the lower magnetic layer 130A, the upper magnetic layer 130B, and a third magnetic layer 130C-within the aperture 160. The integrated inductor 502 also includes the insulation layer 404 of FIG. 4 positioned between the upper magnetic layer 130B and the mold compound 122.

An insulation layer 504, such as a polyimide layer, is between the insulation layer 118 and the mold compound 122, and the third magnetic layer 130C is on the insulation layer 504. Although three magnetic layers 130 are depicted in the integrated inductor 502, in other implementations additional magnetic layers 130 can be included inside the aperture 160. For example, one or more additional instances of a magnetic layer 130 on an insulation layer can be inserted above the third magnetic layer 130C, below the third magnetic layer 130C, or both.

In general, additional magnetic layers 130 provide increased inductance. As a result, the integrated inductor 502 having three magnetic layers 130 can have higher inductance as compared to the integrated inductor 102 of FIG. 1 that has two magnetic layers 130. Thus, a technical benefit of including the third magnetic layer 130C is that the resulting integrated inductor 502 can provide higher inductance in the same footprint as the integrated inductor 102.

While each of FIGS. 1-5 illustrate examples of integrated inductors having particular arrangements of insulation layers, magnetic layers, and mold compound, other implementations may include one or more additional layers, one or more fewer layers, or one or more different layers. For example, one or more polyimide or other layers may be used in place of part (or all) of the mold compound 122 in some implementations. Further, while FIGS. 1-5 illustrate integrated inductors on a wafer and used in conjunction with PMIC circuitry as an example, in other examples such integrated inductors may instead be used in conjunction with an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, and/or combinations thereof.

FIG. 6A depicts a schematic top plan view, and FIG. 6B depicts a schematic perspective view, of a device 600 that includes the integrated inductor 102 within or on a package substrate 604. FIG. 6C depicts a schematic cross sectional profile view of a portion of the integrated inductor 102. The integrated inductor 102 is configured as a seven-turn solenoid and includes a first row of seven conductive pillars 120 including conductive pillars 120A, 120C, 120E, 120G, 120I, 120K, and 120M. The integrated inductor 102 also includes a second row of seven conductive pillars 120 including the conductive pillar 120B. The magnetic layer 130A and the magnetic layer 130B are between the first row of conductive pillars and the second row of conductive pillars and extend the length of the integrated inductor 102.

The second set of conductive lines 126 include seven conductive lines 126A-G that are arranged to electrically connect each of the conductive pillars 120 in the first row to the corresponding conductive pillar 120 in the second row. For example, the conductive line 126A electrically connects the conductive pillar 120A in the first row to the conductive pillar 120B in the second row.

The first set of conductive lines 116 includes eight conductive lines 116A-H. The conductive line 116A electrically connects an inductor input 610 (e.g., a contact pad and/or one of the solder balls 140A, 140B) to the conductive pillar 120A in the first row. The conductive lines 116B-G are arranged to electrically connect each of the conductive pillars 120 in the second row to the next conductive pillar 120 in the first row. For example, the conductive line 116B electrically connects the conductive pillar 120B in the second row to the next conductive pillar 120C in the first row. The conductive line 116H electrically connects the last conductive pillar 120 in the second row to an inductor output 612 (e.g., a contact pad and/or the other of the solder balls 140A, 140B).

Thus, current following a current path through the 3D solenoid configuration of the integrated inductor 102 begins at the inductor input 610 and flows along the conductive line 116A, up the conductive pillar 120A, along the conductive line 126A to the conductive pillar 120B, and down the conductive pillar 120B to complete a first solenoid loop of the integrated inductor 102. The current flows in a similar manner along the remaining six solenoid loops formed via the conductive lines 116A-116H, the conductive lines 126B-126G, and the conductive pillars 120, and exits along the conductive line 116H to the inductor output 612.

In a particular implementation, the device 600 corresponds to a test device in which the integrated inductor 102 is configured as a seven-turn solenoid that is approximately 1 mm long (e.g., a distance from the conductive line 126A to the conductive line 126G is approximately 1 mm) and 0.33 mm wide (e.g., a distance from the conductive pillar 120A to the conductive pillar 120B is approximately 0.33 mm). With the height of the conductive pillars 120 and the thickness of the mold compound 122 in the range of approximately 75 to 100 micrometers, the conductive lines 116 and the conductive lines 126 each having a thickness of approximately 12 micrometers, and the magnetic layer 130A and the magnetic layer 130B each having a thickness of approximately 4 micrometers, the inductance of approximately 11 nH that was previously described with reference to FIG. 1 may be achieved.

Although the device 600 is depicted as including the integrated inductor 102, in other implementations the device 600 may instead, or additionally, include one or more of the integrated inductor 202, the integrated inductor 302, the integrated inductor 402, or the integrated inductor 502.

### Exemplary Sequence for Fabricating an Integrated Inductor Comprising Magnetic Layer(s)

In some implementations, fabricating an integrated inductor that includes one or more magnetic layers (e.g., any of the integrated inductors 102, 202, 302, 402, or 502) includes several processes. FIGS. 7A-C illustrate an exemplary sequence for providing or fabricating an integrated inductor that includes one or more magnetic layers, as described with reference to any of FIGS. 1-6C. In some implementations, the sequence of FIGS. 7A-7C may be used to provide (e.g., during fabrication of) one or more of the devices 100, 200, 300, 400, 500, or 600 of FIGS. 1-6C.

It should be noted that the sequence of FIGS. 7A-7C may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 7A-7C.

Stage 1 of FIG. 7A illustrates a state after a first layer 712 has been formed on a substrate 710, such as a wafer, and patterned to form openings 713A, 713B exposing portions of a surface of the substrate 710. The openings 713 can be formed using patterning operations, etching processes, drilling operations, laser ablation operations, other targeted removal operations, or combinations thereof. In a particular implementation, the substrate 710 is a PMIC wafer, and the first layer 712 is a first polyimide layer that is coated onto the substrate 710 and patterned. According to an aspect, the substrate 710 corresponds to the substrate 110 of FIG. 1, and the first layer 712 corresponds to the insulation layer 112.

Stage 2 illustrates a state after formation of vias 714A, 714B of a first via layer (“V0”) and conductive lines 716 of a first redistribution layer. For example, the vias 714A. 714B and the conductive lines 716 may be formed by applying a metal material (e.g., copper) into the openings 713A, 713B of the first layer 712 and over a surface of the first layer 712. To illustrate, the metal material may be applied to form the vias 714 and the conductive lines 716 using one or more plating processes (e.g., electroplating) and one or more patterning processes. For example, a photoresist process may be performed to generate a pattern to guide the structure and position of the conductive lines 716, and a photoresist ashing or stripping operation may be performed to remove the photoresist layer(s) after formation of the conductive lines 716. Although not shown in the accompanying figures, such photoresist layers can be used during deposition and/or etching processes. Similarly, other processing steps may be performed, such as cleaning, planarization, etc., that may also be omitted from the accompanying figures and/or description. According to an aspect, the vias 714 correspond to the vias 114 of FIG. 1, and the conductive lines 716 correspond to the conductive lines 116.

Stage 3 illustrates a state after a second layer 718 has been formed over the conductive lines 716 and the first layer 712, and a first magnetic layer 730A has been formed on the second layer 718. In a particular implementation, the second layer 718 is a second polyimide layer that is coated onto the conductive lines 716 and the first layer 712. The first magnetic layer 730A may be formed by applying photoresist to the surface of the second layer 718 and performing one or more sputter deposition processes. In a particular implementation, the first magnetic layer 730A includes one or more of CoZrTa, CoZrTaB, or FeCoB. According to an aspect, the second layer 718 corresponds to the insulation layer 118 of FIG. 1, and the first magnetic layer 730A corresponds to the magnetic layer 130A.

Stage 4 illustrates a state after formation of vias 719A, 719B of a second via layer (“V1”) and pillars 720A. 720B of a third via layer (“V2”). In a particular implementation, the vias 719 and the pillars 720 are formed by creating openings in the second layer 718 to expose portions of the conductive lines 716, followed by one or more plating processes (e.g., electroplating). The openings in the second layer 718 can be formed using patterning operations, etching processes, drilling operations, laser ablation operations, other targeted removal operations, or combinations thereof. Prior to the plating process, a photoresist patterning process may be performed to guide the structure and position of the pillars 720, and a photoresist ashing or stripping operation may be performed after formation of the pillars 720. In some implementations, the pillars 720 correspond to megapillars, and the vias 719 and the pillars 720 are formed of copper. According to an aspect, the pillars 720 correspond to the pillars 120 of FIG. 1.

Stage 5 of FIG. 7B illustrates a state after application of a mold compound 722 and back grinding to form a substantially flat top surface of the mold compound 722 and the pillars 720. In a particular example, a deposition process, a spin-on process, or a similar process can be used to apply the mold compound 722, and the mold compound 722 can subsequently be cured or hardened by exposure to light, heat, and/or chemical hardening agents. According to an aspect, the mold compound 722 corresponds to the mold compound 122 of FIG. 1.

Stage 6 illustrates a state after a third layer 723 has been formed over the mold compound 722 and the upper surfaces of the pillars 720, and a second magnetic layer 730B has been formed on the third layer 723. In a particular implementation, the third layer 723 is a third polyimide layer that is coated onto the mold compound 722 and the upper surfaces of the pillars 720. The second magnetic layer 730B may be formed by forming a patterned photoresist layer on the surface of the third layer 723 and performing one or more sputter deposition processes, followed by a photoresist ashing or stripping operation. In a particular implementation, the second magnetic layer 730B includes one or more of CoZrTa, CoZrTaB, or FeCoB. According to an aspect, the third layer 723 corresponds to the insulation layer 404 of FIG. 4, and the second magnetic layer 730B corresponds to the magnetic layer 130B.

Stage 7 illustrates a state after a fourth layer 724 has been formed over the third layer 723 and the second magnetic layer 730B and patterned to form openings 725A, 725B exposing portions of upper surfaces of the pillars 720. In a particular implementation, the fourth layer 724 is a polyimide layer that is coated onto the third layer 723 and the second magnetic layer 730B. The openings 725 can be formed using patterning operations, etching processes, drilling operations, laser ablation operations, other targeted removal operations, or combinations thereof. According to an aspect, the fourth layer 724 corresponds to the insulation layer 124 of FIG. 1.

Stage 8 of FIG. 7C illustrates a state after formation of vias 727A, 727B of a fourth via layer (“V3”) and conductive lines 726 of a second redistribution layer. For example, the vias 727 and the conductive lines 726 may be formed by applying a metal material (e.g., copper) into the openings 725 and over a surface of the fourth layer 724. To illustrate, the metal material may be applied to form the vias 727 and the conductive lines 726 using one or more plating processes (e.g., electroplating) and one or more patterning processes. According to an aspect, the conductive lines 726 correspond to the conductive lines 126 of FIG. 1.

Stage 9 illustrates a state after a fifth layer 728 has been formed over the fourth layer 724 and the conductive lines 726 and patterned to form openings 729A, 729B exposing portions of an upper surface of the conductive lines 726. In a particular implementation, the fifth layer 728 is a polyimide layer that is coated onto the fourth layer 724 and the exposed portions of the conductive lines 726. The openings 729 can be formed using patterning operations, etching processes, drilling operations, laser ablation operations, other targeted removal operations, or combinations thereof. According to an aspect, the fifth layer 728 corresponds to the insulation layer 128 of FIG. 1.

Stage 10 illustrates a state after formation of solder balls 740A, 740B. For example, one or more plating processes and one or more patterning processes can be used form the solder balls 740. In another example, the solder balls 740 may be inserted or dropped into place. According to an aspect, the solder balls 740 correspond to the solder balls 140 of FIG. 1.

Formation of the integrated inductor 702 is completed after Stage 10 of FIG. 7C. However, in some implementations, one or more of Stages 1-10 can be modified or skipped, one or more stages added, or a combination thereof. To illustrate, in a first example, Stage 3 can be modified to omit formation of the first magnetic layer 730A so that the integrated inductor 702 does not include a lower magnetic layer, such as to produce the integrated inductor 302 of FIG. 3.

In a second example, Stage 6 can be skipped to omit formation of the third layer 723 and the second magnetic layer 730B so that the integrated inductor 702 does not include an upper magnetic layer, such as to produce the integrated inductor 202 of FIG. 2.

In a third example, Stage 6 can be modified to omit formation of the third layer 723 so that the second magnetic layer 730B is formed on the mold compound 722, such as to produce the integrated inductor 102 of FIG. 1.

In a fourth example, one or more additional stages can be added between Stage 3 and Stage 4 to form one or more additional magnetic layers. Each of the additional stages can include forming an additional layer onto the upper surface of the existing structure (e.g., by coating a polyimide layer onto the upper surface) and forming a magnetic layer on the additional layer, in a similar manner as described for forming the second layer 718 and the first magnetic layer 730A in Stage 3. To illustrate, adding one such additional stage after Stage 3 may result in the integrated inductor 702 having the third magnetic layer 130C on the insulation layer 504 as depicted in FIG. 5, and the resulting integrated inductor 702 may correspond to the integrated inductor 502 of FIG. 5.

### Exemplary Flow Diagram of a Method for Fabricating an Integrated Inductor Comprising Magnetic Layer(s)

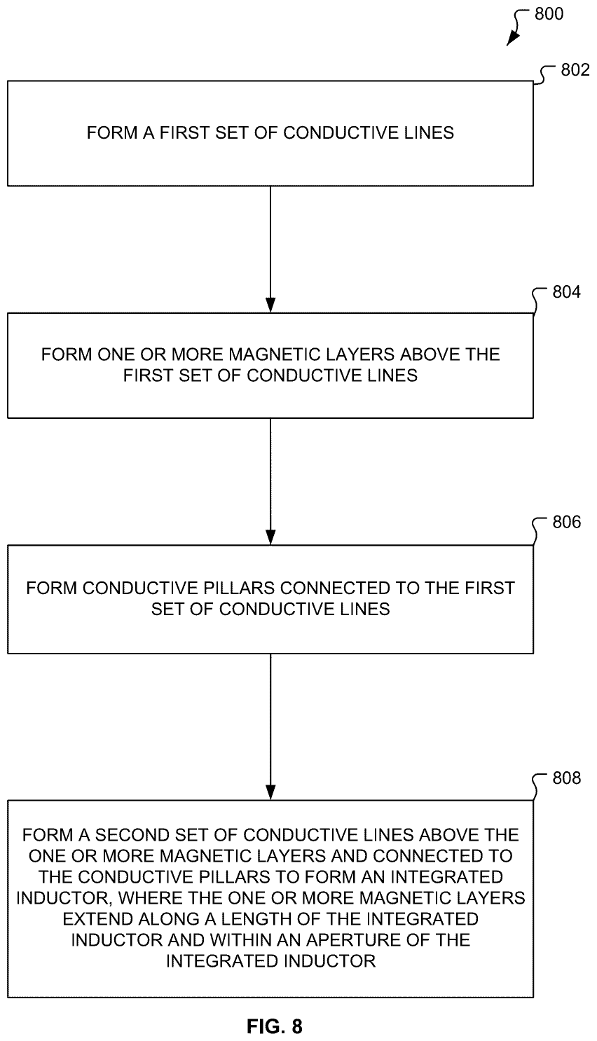

In some implementations, fabricating an integrated inductor that includes one or more magnetic layers includes several processes. FIG. 8 illustrates an exemplary flow diagram of a method 800 for providing or fabricating an integrated inductor that includes one or more magnetic layers. In some implementations, the method 800 of FIG. 8 may be used to provide or fabricate any of the integrated inductors 102, 202, 302, 402, or 502 of FIGS. 1-5.

It should be noted that the method 800 of FIG. 8 may combine one or more processes in order to simplify and/or clarify the method for providing or fabricating an integrated inductor. In some implementations, the order of the processes may be changed or modified.

The method 800 includes, at block 802, forming a first set of conductive lines. For example, the first set of conductive lines can correspond to the first set of conductive lines 116 formed above the surface 142 of any of the devices 100, 200, 300, 400, 500, or 600. In some implementations, Stage 1 and Stage 2 of FIG. 7A illustrate and describe examples of forming a first set of conductive lines above the surface of a wafer.

The method 800 includes, at block 804, forming one or more magnetic layers above the first set of conductive lines. In a particular implementation, the one or more magnetic layers include one or more of CoZrTa, CoZrTaB, or FeCoB. For example, the one or more magnetic layers can correspond to the one or more magnetic layers 130 of any of the devices 100, 200, 300, 400, 500, or 600 and can include the magnetic layer 130A of any of the devices 100, 200, 400, 500, or 600, the magnetic layer 130B of any of the devices 100, 300, 400, 500, or 600, the magnetic layer 130C of the device 500, or any combination thereof. In some implementations, Stage 3 of FIG. 7A and Stage 6 of FIG. 7B illustrate and describe examples of forming magnetic layers above a first set of conductive lines.

The method 800 includes, at block 806, forming conductive pillars connected to the first set of conductive lines. For example, the conductive pillars can correspond to the conductive pillars 120 of any of the devices 100, 200, 300, 400, 500, or 600. In some implementations, Stage 4 of FIG. 7A illustrates and describes an example of forming conductive pillars connected to the first set of conductive lines.

The method 800 includes, at block 808, forming a second set of conductive lines above the one or more magnetic layers and connected to the conductive pillars to form an integrated inductor, where the one or more magnetic layers extend along a length of the integrated inductor and within an aperture of the integrated inductor. For example, the second set of conductive lines can correspond to the second set of conductive lines 126 that are formed above the one or more magnetic layers 130 and that are connected to the conductive pillars 120 to form the integrated inductor of any of the devices 100, 200, 300, 400, 500, or 600. In some implementations, Stage 7 of FIG. 7B and Stage 8 of FIG. 7C illustrate and describe an example of forming a second set of conductive lines above one or more magnetic layers and connected to conductive pillars.

Optionally, the method 800 includes at least partially encapsulating the conductive pillars in a mold compound. For example, the mold compound may correspond to the mold compound 122 of any of the devices 100, 200, 300, 400, or 500, and Stage 5 of FIG. 7B illustrates and describes an example of at least partially encapsulating conductive pillars in a mold compound. In some implementations, the method 800 also includes forming an insulation layer above the first set of conductive lines, where a magnetic layer of the one or more magnetic layers is above the insulation layer and below the mold compound. For example, the magnetic layer can correspond to the magnetic layer 130A that is above the insulation layer 118 and below the mold compound 122, and Stage 3 of FIG. 7A illustrates and describes an example of forming an insulation layer and a magnetic layer above a first set of conductive lines and below a mold compound.

In other implementations, the method 800 includes forming a first insulation layer above the first set of conductive lines, where a first magnetic layer of the one or more magnetic layers is above the first insulation layer, and also forming a second insulation layer above the first insulation layer and the first magnetic layer, where a second magnetic layer of the one or more magnetic layers is above the second insulation layer and below the mold compound. For example, the first insulation layer can correspond to the insulation layer 118, the first magnetic layer can correspond to the magnetic layer 130A, the second insulation layer can correspond to the insulation layer 504, and the second magnetic layer can correspond to the magnetic layer 130C of FIG. 5.

Optionally, a magnetic layer is formed above the mold compound, and an insulation layer is above the magnetic layer and below the second set of conductive lines. For example, the magnetic layer 130B of devices 100, 300, 400, 500, or 600 is formed above the mold compound 122, and the insulation layer 124 is above the magnetic layer 130B and below the second set of conductive lines 126. In some implementations, Stage 7 of FIG. 7B illustrates and describes an example of forming a magnetic layer above a mold compound, and forming an insulation layer above the magnetic layer and below a second set of conductive lines.

Optionally, the integrated inductor is formed on a surface of a power management integrated circuit (PMIC), and an input of the integrated inductor is coupled to circuitry of the PMIC. For example, the via 114A of FIG. 1 can couple an input of the integrated inductor 102 to the active circuitry 144.

### Exemplary Electronic Devices

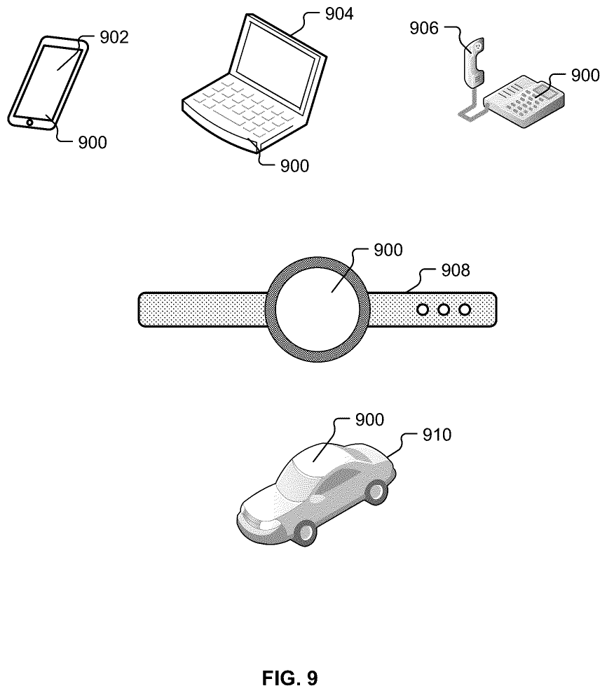

FIG. 9 illustrates various electronic devices that may include or be integrated with any of the device 100, 200, 300, 400, 500, or 600. For example, a mobile phone device 902, a laptop computer device 904, a fixed location terminal device 906, a wearable device 908, or a vehicle 910 (e.g., an automobile or an aerial device) may include a device 900. The device 900 can include, for example, any of the devices 100, 200, 300, 400, 500, or 600 and/or any of the integrated inductors 102, 202, 302, 402, or 502 described herein. The devices 902, 904, 906 and 908 and the vehicle 910 illustrated in FIG. 9 are merely exemplary. Other electronic devices may also feature the device 900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-9 may be rearranged and/or combined into a single component, process, feature or function or embodied in several components, processes, or functions. Additional elements, components, processes, and/or functions may also be added without departing from the disclosure. It should also be noted FIGS. 1-9 and its corresponding description in the present disclosure is not limited to dies and/or ICs. In some implementations, FIGS. 1-9 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to a second component, may be the first component, the second component, the third component, or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, an inductive device includes a first set of conductive lines; a second set of conductive lines; conductive pillars connecting the first set of conductive lines to the second set of conductive lines to form an integrated inductor; and one or more magnetic layers extending along a length of the integrated inductor and within an aperture of the integrated inductor.

Example 2 includes the inductive device of Example 1, wherein the integrated inductor is within or on a package substrate.

Example 3 includes the inductive device of Example 1 or Example 2, wherein the one or more magnetic layers include one or more of CoZrTa, CoZrTaB, or FeCoB.

Example 4 includes the inductive device of any of Examples 1 to 3, wherein the first set of conductive lines is above a wafer surface, wherein a magnetic layer of the one or more magnetic layers is above the first set of conductive lines and below the second set of conductive lines, and further comprising a mold compound between the first set of conductive lines and the second set of conductive lines.

Example 5 includes the inductive device of Example 4, wherein the mold compound includes an epoxy material.

Example 6 includes the inductive device of Example 4 or Example 5 and further includes an insulation layer between the magnetic layer and the first set of conductive lines or the second set of conductive lines.

Example 7 includes the inductive device of Example 6, wherein the insulation layer includes a polyimide material.

Example 8 includes the inductive device of Example 6 or Example 7, wherein the insulation layer is between the magnetic layer and the first set of conductive lines, and wherein the magnetic layer is below the mold compound.

Example 9 includes the inductive device of Example 6 or Example 7, wherein the insulation layer is between the magnetic layer and the second set of conductive lines, and wherein the magnetic layer is above the mold compound.

Example 10 includes the inductive device of any of Examples 1 to 9, wherein the one or more magnetic layers includes two magnetic layers within the aperture.

Example 11 includes the inductive device of any of Examples 1 to 9, wherein the one or more magnetic layers includes three magnetic layers within the aperture.

Example 12 includes the inductive device of any of Examples 1 to 11, wherein the first set of conductive lines are in a first redistribution layer, and wherein the second set of conductive lines are in a second redistribution layer.

Example 13 includes the inductive device of any of Examples 1 to 12, wherein the integrated inductor is formed on a surface of a power management integrated circuit (PMIC), and wherein an input of the integrated inductor is coupled to circuitry of the PMIC.

Example 14 includes the inductive device of any of Examples 1 to 13, wherein at least one of an input of the integrated inductor and an output of the integrated inductor is coupled to a solder ball.

According to Example 15, a device includes an integrated device that includes a first set of conductive lines; a second set of conductive lines; conductive pillars connecting the first set of conductive lines to the second set of conductive lines to form an integrated inductor; and one or more magnetic layers extending along a length of the integrated inductor and within an aperture of the integrated inductor.

Example 16 includes the device of Example 15 and further includes a package substrate, and wherein the integrated inductor is within or on the package substrate.

Example 17 includes the device of Example 15 or Example 16, wherein the one or more magnetic layers include one or more of CoZrTa, CoZrTaB, or FeCoB.

Example 18 includes the device of any of Examples 15 to 17, wherein the first set of conductive lines is above a wafer surface, wherein a magnetic layer of the one or more magnetic layers is above the first set of conductive lines and below the second set of conductive lines, and further comprising a mold compound between the first set of conductive lines and the second set of conductive lines.

Example 19 includes the device of Example 18, wherein the mold compound includes an epoxy material.

Example 20 includes the device of Example 18 or Example 19 and further includes an insulation layer between the magnetic layer and the first set of conductive lines or the second set of conductive lines.

Example 21 includes the device of Example 20, wherein the insulation layer includes a polyimide material.

Example 22 includes the device of Example 20 or Example 21, wherein the insulation layer is between the magnetic layer and the first set of conductive lines, and wherein the magnetic layer is below the mold compound.

Example 23 includes the device of Example 20 or Example 21, wherein the insulation layer is between the magnetic layer and the second set of conductive lines, and wherein the magnetic layer is above the mold compound.

Example 24 includes the device of any of Examples 15 to 23, wherein the one or more magnetic layers includes one magnetic layer within the aperture.

Example 25 includes the device of any of Examples 15 to 23, wherein the one or more magnetic layers includes multiple magnetic layers within the aperture.

Example 26 includes the device of any of Examples 15 to 23, wherein the one or more magnetic layers includes two magnetic layers within the aperture.

Example 27 includes the device of any of Examples 15 to 23, wherein the one or more magnetic layers includes three magnetic layers within the aperture.

Example 28 includes the device of any of Examples 15 to 27, wherein the first set of conductive lines are in a first redistribution layer, and wherein the second set of conductive lines are in a second redistribution layer.

Example 29 includes the device of any of Examples 15 to 28, wherein the integrated inductor is formed on a surface of a power management integrated circuit (PMIC), and wherein an input of the integrated inductor is coupled to circuitry of the PMIC.

Example 30 includes the device of any of Examples 15 to 29, wherein at least one of an input of the integrated inductor and an output of the integrated inductor is coupled to a solder ball.

According to Example 31, a method of fabricating an inductive device includes forming a first set of conductive lines; forming one or more magnetic layers above the first set of conductive lines; forming conductive pillars connected to the first set of conductive lines; and forming a second set of conductive lines above the one or more magnetic layers and connected to the conductive pillars to form an integrated inductor, wherein the one or more magnetic layers extend along a length of the integrated inductor and within an aperture of the integrated inductor.

Example 32 includes the method of Example 31, wherein the one or more magnetic layers include one or more of CoZrTa, CoZrTaB, or FeCoB.

Example 33 includes the method of Example 31 or Example 32, wherein the first set of conductive lines is above a wafer surface.

Example 34 includes the method of any of Examples 31 to 33 and further includes at least partially encapsulating the conductive pillars in a mold compound.

Example 35 includes the method of Example 34, wherein the mold compound includes an epoxy material.

Example 36 includes the method of Example 34 or Example 35 and further includes forming an insulation layer above the first set of conductive lines, and wherein a magnetic layer of the one or more magnetic layers is above the insulation layer and below the mold compound.

Example 37 includes the method of Example 36, wherein the insulation layer includes a polyimide material.

Example 38 includes the method of Example 34 or Example 35 and further includes forming a first insulation layer above the first set of conductive lines, wherein a first magnetic layer of the one or more magnetic layers is above the first insulation layer; and forming a second insulation layer above the first insulation layer and the first magnetic layer, wherein a second magnetic layer of the one or more magnetic layers is above the second insulation layer and below the mold compound.

Example 39 includes the method of any of Examples 34 to 38, wherein a magnetic layer is above the mold compound, and wherein an insulation layer is above the magnetic layer and below the second set of conductive lines.

Example 40 includes the method of any of Examples 31 to 39, wherein the integrated inductor is formed on a surface of a power management integrated circuit (PMIC), and wherein an input of the integrated inductor is coupled to circuitry of the PMIC.

Example 41 includes the method of any of Examples 31 to 40, wherein the integrated inductor is within or on a package substrate.

Example 42 includes the method of any of Examples 31 to 41, wherein the first set of conductive lines are in a first redistribution layer, and wherein the second set of conductive lines are in a second redistribution layer.

Example 43 includes the method of any of Examples 31 to 42, wherein at least one of an input of the integrated inductor and an output of the integrated inductor is coupled to a solder ball.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An inductive device comprising:
a first set of conductive lines;
a second set of conductive lines;
conductive pillars connecting the first set of conductive lines to the second set of conductive lines to form an integrated inductor; and
one or more magnetic layers extending along a length of the integrated inductor and within an aperture of the integrated inductor.

2. The inductive device of claim 1, wherein the integrated inductor is within or on a package substrate.

3. The inductive device of claim 1, wherein the one or more magnetic layers include one or more of CoZrTa, CoZrTaB, or FeCoB.

4. The inductive device of claim 1, wherein the first set of conductive lines is above a wafer surface, wherein a magnetic layer of the one or more magnetic layers is above the first set of conductive lines and below the second set of conductive lines, and further comprising a mold compound between the first set of conductive lines and the second set of conductive lines.

5. The inductive device of claim 4, wherein the mold compound includes an epoxy material.

6. The inductive device of claim 4, further comprising an insulation layer between the magnetic layer and the first set of conductive lines or the second set of conductive lines.

7. The inductive device of claim 6, wherein the insulation layer includes a polyimide material.

8. The inductive device of claim 6, wherein the insulation layer is between the magnetic layer and the first set of conductive lines, and wherein the magnetic layer is below the mold compound.

9. The inductive device of claim 6, wherein the insulation layer is between the magnetic layer and the second set of conductive lines, and wherein the magnetic layer is above the mold compound.

10. The inductive device of claim 1, wherein the one or more magnetic layers includes two magnetic layers within the aperture.

11. The inductive device of claim 1, wherein the one or more magnetic layers includes three magnetic layers within the aperture.

12. The inductive device of claim 1, wherein the first set of conductive lines are in a first redistribution layer, and wherein the second set of conductive lines are in a second redistribution layer.

13. The inductive device of claim 1, wherein the integrated inductor is formed on a surface of a power management integrated circuit (PMIC), and wherein an input of the integrated inductor is coupled to circuitry of the PMIC.

14. The inductive device of claim 1, wherein at least one of an input of the integrated inductor and an output of the integrated inductor is coupled to a solder ball.

15. A device comprising:
an integrated device comprising:
a first set of conductive lines;
a second set of conductive lines;
conductive pillars connecting the first set of conductive lines to the second set of conductive lines to form an integrated inductor; and
one or more magnetic layers extending along a length of the integrated inductor and within an aperture of the integrated inductor.

16. The device of claim 15, further comprising a package substrate, and wherein the integrated inductor is within or on the package substrate.

17. The device of claim 15, wherein the one or more magnetic layers include one or more of CoZrTa, CoZrTaB, or FeCoB.

18. The device of claim 15, wherein the first set of conductive lines is above a wafer surface, wherein a magnetic layer of the one or more magnetic layers is above the first set of conductive lines and below the second set of conductive lines, and further comprising a mold compound between the first set of conductive lines and the second set of conductive lines.

19. The device of claim 15, wherein the one or more magnetic layers includes one magnetic layer within the aperture.

20. The device of claim 15, wherein the one or more magnetic layers includes multiple magnetic layers within the aperture.

21. The device of claim 15, wherein the first set of conductive lines are in a first redistribution layer, and wherein the second set of conductive lines are in a second redistribution layer.

22. The device of claim 15, wherein the integrated inductor is formed on a surface of a power management integrated circuit (PMIC), and wherein an input of the integrated inductor is coupled to circuitry of the PMIC.

23. A method of fabricating an inductive device, the method comprising:
forming a first set of conductive lines;
forming one or more magnetic layers above the first set of conductive lines;
forming conductive pillars connected to the first set of conductive lines; and
forming a second set of conductive lines above the one or more magnetic layers and connected to the conductive pillars to form an integrated inductor,
wherein the one or more magnetic layers extend along a length of the integrated inductor and within an aperture of the integrated inductor.

24. The method of claim 23, wherein the one or more magnetic layers include one or more of CoZrTa, CoZrTaB, or FeCoB.

25. The method of claim 23, wherein the first set of conductive lines is above a wafer surface.

26. The method of claim 23, further comprising at least partially encapsulating the conductive pillars in a mold compound.

27. The method of claim 26, further comprising forming an insulation layer above the first set of conductive lines, and wherein a magnetic layer of the one or more magnetic layers is above the insulation layer and below the mold compound.

28. The method of claim 26, further comprising:
forming a first insulation layer above the first set of conductive lines, wherein a first magnetic layer of the one or more magnetic layers is above the first insulation layer; and
forming a second insulation layer above the first insulation layer and the first magnetic layer, wherein a second magnetic layer of the one or more magnetic layers is above the second insulation layer and below the mold compound.

29. The method of claim 26, wherein a magnetic layer is above the mold compound, and wherein an insulation layer is above the magnetic layer and below the second set of conductive lines.

30. The method of claim 23, wherein the integrated inductor is formed on a surface of a power management integrated circuit (PMIC), and wherein an input of the integrated inductor is coupled to circuitry of the PMIC.
